(19) United States
(12) Patent Application Publication
(10) Pub. No.: US 2026/0282993 A1
(43) Pub. Date: Sep. 17, 2026

(54) SOLDER BONDING MEMBER, SEMICONDUCTOR DEVICE, SOLDER BONDING METHOD, AND METHOD FOR MANUFACTURING SEMICONDUCTOR DEVICE

(71) Applicant: Mitsubishi Electric Corporation, Tokyo (JP)

(72) Inventor: Koji YAMAZAKI, Chiyoda-ku, Tokyo (JP)

(73) Assignee: Mitsubishi Electric Corporation, Tokyo (JP)

(21) Appl. No.: 18/871,499

(22) PCT Filed: Jun. 20, 2022
(86) PCT No.: PCT/JP2022/024565

§ 371 Date: Dec. 4, 2024

(51) Int. Cl. H10W 72/30; H10W 72/00; H10W 90/00

(52) U.S. Cl. CPC H10W 72/352; H10W 72/07336; H10W 90/734

(57) ABSTRACT

A solder bonding member to bond a first object and a second object contains Sn serving as a main component, 3 mass % or more and less than 4 mass % of Ag, 0.5 mass % or more and less than 1.0 mass % of Cu, 2.5 mass % or more and less than 4 mass % of Bi, and 0.5 mass % or more and less than 3 mass % of Sb, and includes: a main phase containing Sn, Ag and Cu and having a melting point of 210° C. or more and less than 220° C.; a Sn—Bi—Sb alloy phase covering at least a portion of the main phase and having a melting point of 170° C. or more and less than 180° C.; and a Sn—Bi alloy phase covering at least a portion of the Sn—Bi—Sb alloy phase and having a melting point of 135° C. or more and less than 145° C.

### TECHNICAL FIELD

The present disclosure relates to a solder bonding member, a semiconductor device, a solder bonding method, and a method for manufacturing the semiconductor device.

### BACKGROUND ART

In recent years, higher reliability of a semiconductor device including a semiconductor element and a circuit board has been required. In such a semiconductor device, the improvement in reliability has been required due to the following reason: since a difference in thermal expansion coefficient between the semiconductor element and the circuit board is large particularly at a bonding portion (bonded body) between the semiconductor element and the circuit board, a defect is likely to occur.

On the other hand, in order to reduce an environmental load, a lead-free solder containing no lead (Pb), which is a substance regulated for the sake of environment, has been employed as a solder used to bond such a bonding portion. As a representative conventional lead-free solder, a solder having a composition of Sn-3Ag-0.5Cu (wt %) (Sn-3Ag-0.5Cu solder) has been known.

The melting point of the Sn-3Ag-0.5Cu solder is 220° C. In order to increase flowablility by melting the lead-free solder (spreading the solder in a wet state on the surface to be bonded), it is necessary to increase a heating temperature to about 250° C., which is higher than the melting point by 30° C. During subsequent cooling, the bonded member is warped or has high residual stress accumulated therein due to thermal contraction. Therefore, in an evaluation (heat cycle test or power cycle test) on the reliability of bonding after the cooling, the stress is released and a crack is likely to be produced in the solder bonding portion at an early stage.

In order to reduce such residual stress after the solder bonding, Bi, In, or the like each having an effect of lowering the melting point is added to the Sn-3Ag-0.5Cu solder.

For example, PTL 1 (Japanese Patent Laying-Open No. 2002-120085) discloses that a lead-free solder alloy has a melting temperature lower than 215° C. and substantially consists of 76 to 96% of tin, 0.2 to 2.5% of copper, 2.5 to 4.5% of silver, and more than 0 and up to 12% of indium. It is described that it is thus possible to provide a lead-free solder that has an appropriate melting temperature range (175 to 210° C.) useful for mainstream electronic manufacturing and that provides high strength and high fatigue resistance.

Further, PTL 2 (Japanese Patent Laying-Open No. 2018-149558) discloses a lead-free solder alloy containing 1 mass % or more and 4 mass % or less of Ag, 0.1 mass % or more and 1 mass % or less of Cu, 1.5 mass % or more and 5 mass % or less of Sb, and 1 mass % or more and 6 mass % or less of In with the remainder being Sn. Further, a lead-free solder alloy further containing 1 mass % or more and 5.5 mass % or less of Bi in addition to the above-described composition is also disclosed.

It should be noted that PTL 2 discloses that regarding a specific reflow condition (temperature profile), preheating is 170° C. to 190° C. for 110 seconds, a peak temperature is 245° C., a period of time at 200° C. or more is 65 seconds, a period of time at 220° C. or more is 45 seconds, and a rate of cooling from the peak temperature to 200° C. is 3 to 8° C./second.

### CITATION LIST

### Patent Literature

PTL 1: Japanese Patent Laying-Open No. 2002-120085
PTL 2: Japanese Patent Laying-Open No. 2018-149558

### SUMMARY OF INVENTION

### Technical Problem

Each of PTL 1 and PTL 2 has a problem in practical use because no attention is paid to a structure (configuration) of the bonding portion after the solder bonding.

Specifically, Sn, which is a main component of the solder, forms an intermetallic compound at the bonded surface. In the vicinity of an interface between the intermetallic compound and its surroundings, another added element is locally concentrated as compared with Sn that is the main component, thereby forming a phase having a melting point different from the melting point of the solder before use. For example, when the other added element is Bi, a Sn—Bi eutectic phase (melting point: 140° C.) is formed. Therefore, at the time of solidification and contraction after the solder bonding, the main phase is first solidified, and then a phase having a melting point lower than that of the main phase (for example, the Sn—Bi phase) is solidified. Due to such a gap between the timings of solidification, a shrinkage cavity (clearance such as a crevice produced in the solidification process), a stress due to thermal contraction, or the like is caused, with the result that the semiconductor element, which is a bonded member, may be damaged.

Further, when warpage, unevenness, or the like is caused in the bonded member (the semiconductor element or the substrate) after the solder bonding, electrical characteristics of the semiconductor element are changed for each solder bonding portion, thus resulting in a problem in electrical design. Further, when the unevenness is caused in the semiconductor element, stress is applied to the semiconductor element at the time of wire bonding in a subsequent wire bonding step (electric wiring), with the result that the semiconductor element may be cracked or a wire bonding defect may be produced.

It should be noted that in each of PTL 1 and PTL 2, the addition of In has an effect of lowering the melting point of the solder. However, since In is a metal that is likely to be oxidized, voids may be produced due to oxidation of In at the time of initial bonding when the solder contains a large amount of In. Therefore, in practical use, the amount of addition of In needs to be smaller than the amount of addition thereof described in each literature described above.

It is an object of the present disclosure to provide a solder so as to suppress occurrence of a defect resulting from a bonding portion formed using a solder.

### Solution to Problem

A solder bonding member according to the present embodiment is a solder bonding member to bond a first object and a second object, the solder bonding member containing Sn serving as a main component, 3 mass % or more and less than 4 mass % of Ag, 0.5 mass % or more and less than 1.0 mass % of Cu, 2.5 mass % or more and less than 4 mass % of Bi, and 0.5 mass % or more and less than 3 mass % of Sb,
the solder bonding member comprising:
a main phase containing Sn, Ag and Cu and having a melting point of 210° C. or more and less than 220° C.;
a Sn—Bi alloy phase covering at least a portion of the main phase and having a melting point of 135° C. or more and less than 145° C.; and
a Sn—Bi—Sb alloy phase covering at least a portion of the Sn—Bi alloy phase and having a melting point of 170° C. or more and less than 180° C.

### Advantageous Effects of Invention

According to the present disclosure, it is possible to suppress occurrence of a defect resulting from a bonding portion formed using a solder.

Since the solder bonding member according to the present disclosure has the two phases, each of which has a melting point lower than that of the main phase located internally, in the vicinity of a bonding interface with an object (object to be bonded), a stress produced during thermal contraction (solidification and contraction) is relaxed, thereby suppressing occurrence of a defect resulting from the stress. Therefore, a bonding portion having high reliability (as well as a semiconductor device having the bonding portion) is provided.

Further, since the above-described two phases are included, a stress produced after the bonding is also relaxed, thereby providing a bonding portion that can maintain high reliability after the bonding (as well as a semiconductor device having the bonding portion).

### BRIEF DESCRIPTION OF DRAWINGS

FIG. 1 is a flowchart showing a procedure of manufacturing a semiconductor device (semiconductor-element-bonded body).

FIG. 2 is a schematic cross sectional view showing a first step of FIG. 1.

FIG. 3 is a schematic cross sectional view showing a second step of FIG. 1.

FIG. 4 is a schematic cross sectional view showing a third step of FIG. 1.

FIG. 5 is a schematic cross sectional view showing a fourth step of FIG. 1.

FIG. 6 is a schematic cross sectional view showing a fifth step of FIG. 1.

FIG. 7 is a schematic cross sectional view of a bonding interface portion after the fifth step of FIG. 1.

FIG. 8 shows a DSC measurement result of a solder bonding member of an Example 1.

FIG. 9 shows a DSC measurement result of a solder bonding member of a Comparative Example 1.

FIG. 10 shows a result of observation of a cross section of the solder bonding member of Example 1.

FIG. 11 shows a result of observation of a cross section of the solder bonding member of Comparative Example 1.

FIG. 12 is a schematic cross sectional view of the solder bonding member according to the first embodiment.

### DESCRIPTION OF EMBODIMENTS

Hereinafter, embodiments of the present disclosure will be described. It should be noted that in each of the figures, a dimensional relation such as a length, width, thickness, or depth is appropriately changed for the sake of clarity and simplicity of each of the figures, and does not represent an actual dimensional relation.

### First Embodiment

### <Solder Bonding Member>

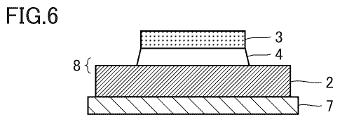

A solder bonding member 4 of the present embodiment is a member to bond a first object 2 (for example, a substrate) and a second object 3 (for example, a semiconductor element) (see FIG. 6). It should be noted that unlike a solder sheet 1 described later, solder bonding member 4 is a member that is composed of a solder (solder alloy) solidified after being melted by a heating step and that exists with solder bonding member 4 being bonded to both the bonded members (the first object and the second object).

Solder bonding member 4 of the present embodiment contains Sn serving as a main component, 3 mass % or more and less than 4 mass % of Ag, 0.5 mass % or more and less than 1.0 mass % of Cu, 2.5 mass % or more and less than 4 mass % of Bi, and 0.5 mass % or more and less than 3 mass % of Sb.

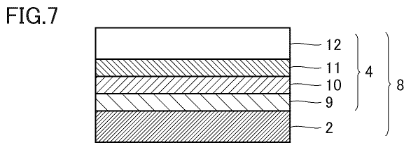

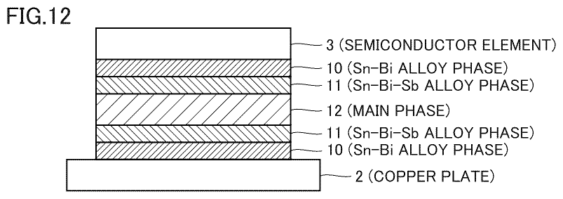

Further, solder bonding member 4 of the present embodiment has:
a main phase 12 (high-melting-point phase) containing Sn, Ag, and Cu and having a melting point of 210° C. or more and less than 220° C.;
a Sn—Bi alloy phase 10 (low-melting-point phase) covering at least a portion of main phase 12 and having a melting point of 135° C. or more and less than 145° C.; and
an Sn—Bi—Sb alloy phase 11 (intermediate-melting-point phase) covering at least a portion of Sn—Bi alloy phase 10 and having a melting point of 170° C. or more and less than 180° C. (see FIGS. 7 and 12).

Thus, solder bonding member 4 of the present embodiment has a multiphase structure with the plurality of separated phases having different melting points.

It should be noted that in solder bonding member 4, Sn—Bi—Sb alloy phase 11 (intermediate-melting-point phase), Sn—Bi alloy phase 10 (low-melting-point phase), and main phase 12 (high-melting-point phase) basically exist in this order from the bonded member (first object 2 or second object 3) side.

Solder bonding member 4 of the present embodiment contains Sn as a main component. Here, the “main component” is a component having the largest amount among the components included in solder bonding member 4. The content ratio of Sn in solder bonding member 4 is preferably 60 mass % or more, is more preferably 70 mass % or more, and is further preferably 80 mass % or more.

In solder bonding member 4 of the present embodiment, the content ratio of Ag is 3 mass % or more and less than 4 mass %, and the content ratio of Cu is 0.5 mass % or more and less than 1.0 mass %. It has been confirmed that the effect of the present disclosure can be obtained when the content ratios of Ag and Cu are respectively within these ranges.

It should be noted that the addition of Ag and Cu has an effect of lowering a melting point such that the melting point of the Sn—Ag—Cu eutectic is 220° C. while the melting point of Sn alone is 232° C. Further, the addition of Ag has an effect of increasing strength by fine dispersion strengthening of a Ag—Sn compound. The addition of Cu has an effect of avoiding Sn from forming a coarse interface compound at the bonding interface. It should be noted that when no Cu exists, a compound reaction at the bonding interface proceeds, Sn disappears, and Bi is likely to be concentrated, so that the amount of addition of Cu is preferably within the above-described range.

It should be noted that solder bonding member 4 may contain an element other than those described above, and may contain, as the other added element, 0.1 mass % or more and less than 1 mass % of In having an effect of lowering a melting point, for example. Also in this case, no bonding property is greatly affected and the same effect as described above can be obtained.

### Second Embodiment

### <Semiconductor Device>

A semiconductor device according to the present embodiment includes substrate 2 and semiconductor element 3. Substrate 2 and semiconductor element 3 are bonded to each other with solder bonding member 4 described in the first embodiment being interposed therebetween. Thus, a semiconductor device having high reliability is provided.

### Third Embodiment

### <Solder Bonding Method>

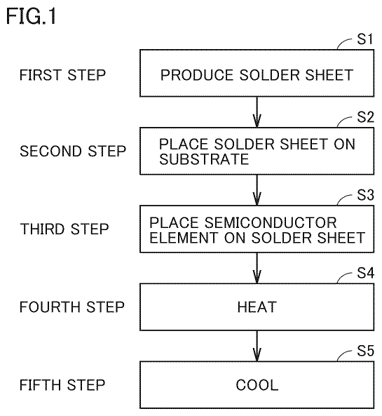

A solder bonding method according to the present embodiment is a solder bonding method for bonding first object 2 (for example, the substrate) and second object 3 (for example, the semiconductor element) (see FIGS. 1 to 6).

The solder bonding method according to the present embodiment includes a heating step of heating solder sheet 1 with solder sheet 1 being sandwiched between first object 2 and second object 3, solder sheet 1 containing Sn serving as a main component, 3 mass % or more and less than 4 mass % of Ag, 0.5 mass % or more and less than 1.0 mass % of Cu, 2.5 mass % or more and less than 4 mass % of Bi, and 0.5 mass % or more and less than 3 mass % of Sb.

With the heating step, solder sheet 1 becomes solder bonding member 4 to bond first object 2 and second object 3. It should be noted that steps other than the heating step will be described later in Examples.

In the heating step, a heating temperature (maximum reaching temperature) is preferably 220° C. or more and less than 230° C., and a heating time (period of time during which the temperature is maintained at 220° C. or more and less than 230° C.) is preferably 10 minutes or more and less than 20 minutes. In this case, the solder bonding member of the present embodiment is formed more securely, thereby obtaining the effect of the above-described solder bonding member.

Further, in the present disclosure, an oxygen concentration in solder sheet 1 is also important. Bi is likely to be oxidized, and if solder sheet 1 is not stored in a vacuum desiccator or the like with Bi being added therein, solder wettability is poor and excellent bonding cannot be obtained. The concentration of oxygen contained in solder sheet 1 is preferably more than 0 ppm and less than 500 ppm, and in this case, the same effect as described above can be more securely obtained.

### Fourth Embodiment

### <Method for Manufacturing Semiconductor Device>

A method for manufacturing a semiconductor device according to the present embodiment is a method for manufacturing a semiconductor device including a substrate and a semiconductor element. The method for manufacturing a semiconductor device according to the present embodiment includes a step of bonding a substrate (substrate wiring such as a copper plate) and a semiconductor element using the solder bonding method according to the third embodiment. Thus, a semiconductor device having high reliability is provided.

### EXAMPLES

Hereinafter, the present disclosure will be described in more detail with reference to Examples, but the present disclosure is not limited to these Examples.

### Example 1

Referring to a flowchart shown in FIG. 1, the following describes an exemplary procedure of producing a semiconductor-element-bonded body (body in which a semiconductor element and a substrate are bonded) in the method for manufacturing a semiconductor device according to the present embodiment.

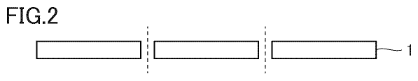

First, as a first step (S1), solder sheet 1 is cut into a predetermined size (see FIG. 2).

Specifically, first, each element was added and dissolved so as to attain a composition represented by Sn-3.5Ag-0.7Cu-3.3Bi-2.0Sb (each numerical value represents mass % and Sn is the remainder of the composition ratios of the other elements) as a representative exemplary solder composition, thereby producing a bulk body.

Next, solder sheet 1 having a shape of roll was produced to have a thickness of 100 μm by performing a rolling process at 100° C. or less. Thereafter, solder sheet 1 was cut into a size of 5 mm×5 mm, which is the same size as the below-described size of the semiconductor element.

It should be noted that solder sheet 1 may be manufactured not only by the rolling but also by melting the bulk body and sequentially introducing the molten solder through a thin slit. Further, when the number of the combined elements is five and is large as described above, the composition of the bulk body may become non-uniform due to a temperature variation in a melting furnace. In this case, the solder composition may be adjusted by first manufacturing a Sn—Ag—Cu bulk body and then adding predetermined amounts of Bi and Sb thereto with the Sn—Ag—Cu bulk body being melted again. Alternatively, solder balls may be formed temporarily, may be dispersed uniformly on a flat plate, and may be subjected to compression molding, thereby manufacturing the sheet.

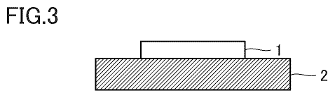

Next, as a second step (S2), solder sheet 1 was placed on substrate 2 (copper plate) (see FIG. 3).

As substrate 2, a plate composed of a tough pitch copper (thickness: 1 mm; size: 10 mm×10 mm) was used. The outermost surface of substrate 2 is pure copper and is not plated.

It should be noted that in order to prevent oxidation, a predetermined amount of an anticorrosive agent that has a decomposition temperature of 100° C. or less and that does not affect the bonding property may be applied to the outermost surface of the CuMo alloy plate. Further, when placing solder sheet 1 thereon, an organic agent that is thermally decomposable at a high temperature of 100° C. or more may be used as a tack material so as to avoid solder sheet 1 from being deviated from the initial position. The viscosity of the tack material is preferably 200 Pa·s or more. Alternatively, a resist film may be applied to a portion of the Cu plate other than the bonding portion so as to avoid solder sheet 1 from being deviated therefrom.

Solder sheet 1 may be warped to some extent at the time of cutting or handling. This is due to the following reason: since solder sheet 1 is completely melted by heating, there is no influence from the initial shape of solder sheet 1. However, if solder sheet 1 is greatly warped to such an extent that no semiconductor element can be placed thereon, solder sheet 1 may be corrected to be parallel on another flat plate because the semiconductor element will be placed thereon in the next step.

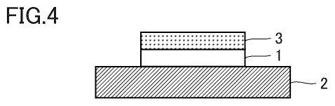

Next, as a third step (S3), semiconductor element 3 was placed on solder sheet 1 (see FIG. 4). Semiconductor element 3 is composed of Si and has a thickness of 100 μm and a size of 5 mm×5 mm. A Ni film is formed on the bonded surface side for the sake of wetting of the solder. Further, in order to fix the placement position, the above-described tack material may be applied between semiconductor element 3 and solder sheet 1.

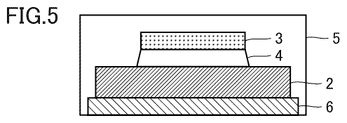

Next, as a fourth step, the stack of the respective members obtained in the above-described steps was placed on a hot plate 6 in a heating furnace 5 (see FIG. 5). Then, formic acid, which is a representative organic acid that can reduce an oxide film, was sealed in heating furnace 5, heating was performed at 180° C. for 5 minutes, and then heating was performed at 230° C. for 10 minutes, thereby melting solder sheet 1 to form solder bonding member 4.

Next, as a fifth step (S5), a sample (semiconductor-element-bonded body) having solder bonding member 4 formed thereon is placed on a cooling plate 7 for the sake of cooling (see FIG. 6).

On this occasion, when the semiconductor element is warped or undulated (unevenness is caused) due to thermal contraction of the solder, electrical characteristics of semiconductor element 3 are varied. Therefore, in the cooling step, the cooling was gradually performed for 360 seconds so as to reach 130° C. at which the sample can be taken out (so as to decrease the temperature by 100° C. from 230° C. to 130° C.).

It should be noted that such a cooling (gradual cooling) step is not performed in a common solder manufacturing process. This is because tact (operation time) of the solder bonding becomes long due to such a gradual cooling step. However, in consideration of the above-described influence on semiconductor element 3, the gradual cooling was performed to decrease the stress as much as possible.

With the above-described steps, the semiconductor-element-bonded body was obtained.

FIG. 7 is a schematic cross sectional view showing a bonding interface portion 8 (a portion located on the solder bonding member 4 side and the substrate 2 side and including the bonding interface therebetween) of the semiconductor-element-bonded body (see FIG. 6) obtained after the fifth step. As shown in FIG. 7, an interface compound 9 (a compound containing a component of substrate 2 and a component of solder sheet 1), Sn—Bi alloy phase 10 (low-melting-point phase), Sn—Bi—Sb alloy phase 11 (intermediate-melting-point phase), and main phase 12 exist in this order from the substrate 2 side in bonding interface portion 8.

It should be noted that the configuration of each phase in the whole of solder bonding member 4 including the substrate 2 side and the semiconductor element 3 side is as shown in FIG. 12.

### <Evaluation>

Semiconductor element 3 was removed from the obtained sample (semiconductor-element-bonded body), and a portion of solder bonding member 4 was shaved off from the semiconductor element 3 side, with the result that only bonding interface portion 8 on the substrate (Cu plate) 2 side was left. It should be noted that since processing oil, polishing waste, moisture, or the like had been introduced onto the sample at the time of production thereof, the sample cleaned with ethanol in advance and left at room temperature for 24 hours after the cleaning was used.

Bonding interface portion 8 of solder bonding member 4 was subjected to differential scanning calorimetry (DSC) measurement. Pt (platinum) was used for a pan in which the sample was placed. The DSC measurement (apparatus) is a method (apparatus) for measuring a state change of the sample, and the melting point of solder bonding member 4 at bonding interface portion 8 can be checked by the DSC measurement. A temperature increasing rate in the DSC measurement was 2° C./minute.

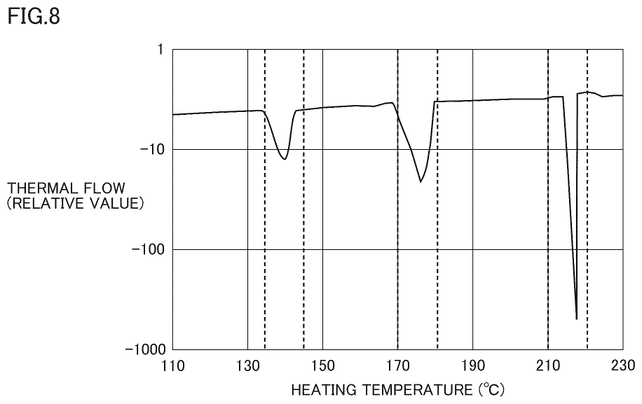

FIG. 8 shows a DSC measurement result of the sample. In FIG. 8, the horizontal axis represents a heating temperature in the DSC measurement, and the vertical axis represents a thermal flow of solder bonding member 4. It should be noted that since an endothermic reaction occurs upon a change from a solid to a liquid, the thermal flow has a negative value. The vertical axis is a logarithmic axis, the unit of the thermal flow is mW, and each of numerical values shown here in FIG. 8 is a relative value (value relative to the Pt pan).

In view of the result shown in FIG. 8, three peaks (reverse peaks) of the thermal flow were mainly observed. These three peaks correspond to the phase having a melting point of 135° C. or more and less than 145° C. (low-melting-point phase: Sn—Bi alloy phase 10), the phase having a melting point of 170° C. or more and less than 180° C. (intermediate-melting-point phase: Sn—Bi—Sb alloy phase 11), and the phase having a melting point of 210° C. or more and less than 220° C. (main phase 12).

In view of this result, in the present example, it can be confirmed that the plurality of phases are formed by the interface reaction at the time of bonding as in bonding interface portion 8 (portion of solder bonding member 4 on the substrate side) after the fifth step shown in FIG. 7.

Next, bonding strength of the sample (semiconductor-element-bonded body) was measured by a die shear test. As a result, the bonding strength was 48 MPa. This value achieves a target value of 40 MPa or more. It should be noted that when a similar bonded body was obtained using a common Sn-3Ag-0.5Cu solder, peel strength of the bonded body was 40 MPa and therefore a higher bonding strength was set as the target value. The bonding strength was high presumably because a solid solution strengthening mechanism functioned in part by adding Bi and Sb to the solder.

Further, an amount of warpage (maximum distance from the substrate) of the semiconductor element in the sample (semiconductor-element-bonded body) was measured. As a result, in the whole of the semiconductor element, the amount of warpage was 10 μm or less, thereby achieving a target of 30 μm or less. On the other hand, when the common Sn-3Ag-0.5Cu solder was used, the amount of warpage was 40 μm, thus failing to achieve the target.

### Comparative Example 1

In order to review the effect of adding Sb, a sample (semiconductor-element-bonded body) was produced in the same manner as in Example 1 except that solder sheet 1 did not contain Sb (solder sheet 1 had a composition of Sn-3.5Ag-0.7Cu-3.3Bi), and was evaluated in the same manner.

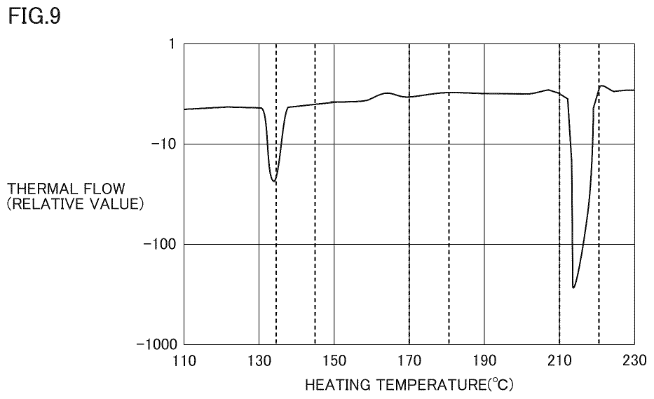

FIG. 9 shows a DSC measurement result of Comparative Example 1. As shown in FIG. 9, the intermediate-melting-point phase was not observed in Comparative Example 1, and the low-melting-point phase fell out of the range of “135° C. or more and less than 145° C.” in Example 1. This is presumably because the added Sb has an effect of increasing the melting point of each of the low-melting-point phase and the intermediate-melting-point phase. It should be noted that regarding main phase 12, a peak corresponding to the phase having a melting point of 210° C. or more and less than 220° C. is observed as in Example 1. This is considered to become more apparent due to Sb being concentrated at the bonding interface.

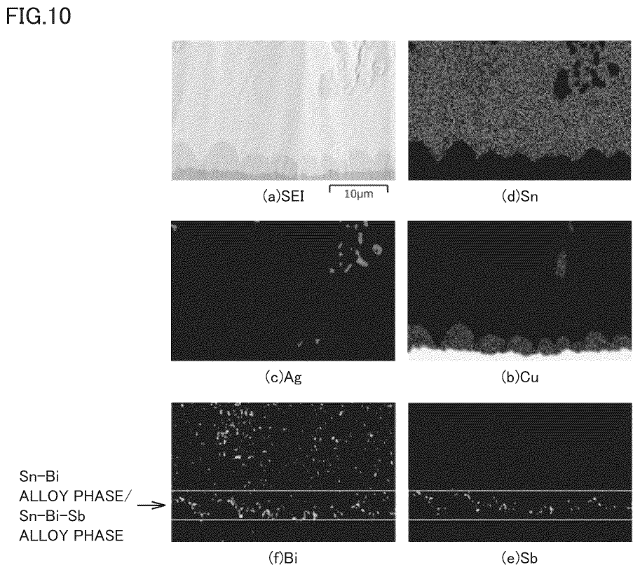

In order to clarify the above-described mechanism, element mapping of solder bonding member 4 of the sample of Example 1 produced using solder sheet 1 (Sn-3.5Ag-0.7Cu-3.3Bi-2.0Sb) containing Sb was performed. As a result, as shown in FIG. 10, it was indicated that Sb and Bi were concentrated particularly in the bonding interface portion and they were the low-melting-point phase and the intermediate-melting-point phase respectively.

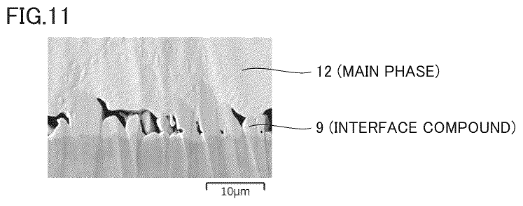

Further, as shown in a SEM photograph of FIG. 11, in the sample of Comparative Example 1 produced using solder sheet 1 (Sn-3.5Ag-0.7Cu-3.3Bi) to which Sb was not added, it was confirmed that a shrinkage cavity resulting from solidification and contraction was formed in interface compound 9. This is presumably due to the following reason: in the case where Sb is not added, when main phase 12 is solidified and then the low-melting-point phase is solidified, the solidifications take place immediately, thus resulting in formation of such a shrinkage cavity. That is, it is considered that the addition of Sb has such an effect that solidification/contraction cracking of the low-melting-point phase is suppressed by the separation of the phases formed at the bonding interface in the gradual cooling process for suppressing residual stress at the bonding portion in the present disclosure.

### Example 2

The amounts of addition of Bi and Sb were changed as shown in Table 1. Apart from this point, occurrence or non-occurrence of solidification cracking was visually checked by a SEM photograph with regard to a bonded sample obtained in the same manner as in Example 1. Results of the check are shown in Table 1. In Table 1, “OK” indicates that there is no solidification cracking, and “NG” indicates that there is solidification cracking.

TABLE 1

| | | Bi (mass %) | | | | | |
|---|---|---|---|---|---|---|---|
| | | 2.3 | 2.5 | 3.0 | 3.5 | 3.8 | 4.0 |
| Sb | 0.0 | NG | NG | NG | NG | NG | NG |
| (mass %) | 0.3 | NG | NG | NG | NG | NG | NG |
| | 0.5 | NG | OK | OK | OK | OK | NG |
| | 2.0 | NG | OK | OK | OK | OK | NG |
| | 2.8 | NG | OK | OK | OK | OK | NG |
| | 3.0 | NG | NG | NG | NG | NG | NG |

In view of the results shown in Table 1, it is understandable that when 2.5 mass % or more and less than 4 mass % of Bi and 0.5 mass % or more and less than 3 mass % of Sb are added, there is no solidification cracking and excellent bonding can be attained. Further, in this case, it was confirmed that the bonding strength of the bonded sample was 40 MPa or more. This is presumably due to the following reason: since there was no solidification cracking (shrinkage cavity), the high bonding strength was maintained. The amount of warpage of the semiconductor element was 10 μm or less, which was also excellent.

When Bi was less than 2.5 mass %, sufficient solder wettability was not obtained, and the bonding strength was insufficient (less than 40 MPa). When Bi was 4 mass % or more, a ratio of the low-melting-point phase was increased, the solidification cracking was caused, and the bonding strength was insufficient (less than 40 MPa).

When Sb was less than 0.5 mass %, the effect by the intermediate-melting-point phase was not sufficiently obtained, the solidification cracking was caused, and the bonding strength was insufficient (less than 40 MPa). When Sb was 3 mass % or more, the melting point of main phase 12 was also increased, sufficient solder wettability was not obtained, and the bonding strength was insufficient (less than 40 MPa).

The embodiments and examples disclosed herein are illustrative and non-restrictive in any respect. The scope of the present disclosure is defined by the terms of the claims, rather than the embodiments described above, and is intended to include any modifications within the scope and meaning equivalent to the terms of the claims.

### REFERENCE SIGNS LIST

1: solder sheet; 2: first object (substrate: copper plate); 3: second object (semiconductor element); 4: solder bonding member; 5: heating furnace; 6: hot plate; 7: cooling plate; 8: bonding interface portion; 9: interface compound; 10: Sn—Bi alloy phase (low-melting-point phase); 11: Sn—Bi—Sb alloy phase (intermediate-melting-point phase); 12: main phase.

1. A solder bonding member to bond a first object and a second object, the solder bonding member containing Sn serving as a main component, 3 mass % or more and less than 4 mass % of Ag, 0.5 mass % or more and less than 1.0 mass % of Cu, 2.5 mass % or more and less than 4 mass % of Bi, and 0.5 mass % or more and less than 3 mass % of Sb,
the solder bonding member comprising:
a main phase containing Sn, Ag and Cu and having a melting point of 210° C. or more and less than 220° C.;
a Sn—Bi—Sb alloy phase covering at least a portion of the main phase and having a melting point of [[135° C.] 170° C. or more and less than [145° C.]] 180° C.; and
a Sn—Bi alloy phase covering at least a portion of the Sn—Bi—Sb alloy phase and having a melting point of 135° C. [170° C.] or more and less than 145° C. [180° C.].

2. The solder bonding member according to claim 1, wherein the solder bonding member further contains 0.1 mass % or more and less than 1 mass % of In.

3. The solder bonding member according to claim 1, wherein the first object is a substrate and the second object is a semiconductor element.

4. A semiconductor device comprising a substrate and a semiconductor element, wherein
the substrate and the semiconductor element are bonded with the solder bonding member according to claim 1 being interposed between the substrate and the semiconductor element.

5. A solder bonding method for bonding a first object and a second object, the solder bonding method comprising heating a solder sheet with the solder sheet being sandwiched between the first object and the second object, the solder sheet containing Sn serving as a main component, 3 mass % or more and less than 4 mass % of Ag, 0.5 mass % or more and less than 1.0 mass % of Cu, 2.5 mass % or more and less than 4 mass % of Bi, and 0.5 mass % or more and less than 3 mass % of Sb, wherein
in the heating, a heating temperature is 220° C. or more and less than 230° C. and a heating time is 10 minutes or more and less than 20 minutes.

6. The solder bonding method according to claim 5, wherein a total amount of oxygen contained in the solder sheet is more than 0 ppm and less than 500 ppm.

7. The solder bonding method according to claim 5, wherein the first object is a substrate and the second object is a semiconductor element.

8. A method for manufacturing a semiconductor device including a substrate and a semiconductor element, the method comprising bonding the substrate and the semiconductor element using the solder bonding method according to claim 7.

9. The solder bonding member according to claim 2, wherein the first object is a substrate and the second object is a semiconductor element.

10. A semiconductor device comprising a substrate and a semiconductor element, wherein
the substrate and the semiconductor element are bonded with the solder bonding member according to claim 9 being interposed between the substrate and the semiconductor element.

11. A semiconductor device comprising a substrate and a semiconductor element, wherein
the substrate and the semiconductor element are bonded with the solder bonding member according to claim 2 being interposed between the substrate and the semiconductor element.

12. A semiconductor device comprising a substrate and a semiconductor element, wherein
the substrate and the semiconductor element are bonded with the solder bonding member according to claim 3 being interposed between the substrate and the semiconductor element.

13. The solder bonding method according to claim 6, wherein the first object is a substrate and the second object is a semiconductor element.

14. A method for manufacturing a semiconductor device including a substrate and a semiconductor element, the method comprising bonding the substrate and the semiconductor element using the solder bonding method according to claim 13.
